(19) United States
(12) Patent Application Publication
(10) Pub. No.: US 2016/0007494 A1
(43) Pub. Date: Jan. 7, 2016

(54) Compact Casing Structure

(71) Applicant: KSFL CO., LTD., Taipei (TW)

(72) Inventor: Rong-San LIN, Taipei (TW)

(21) Appl. No.: 14/687,387

(22) Filed: Apr. 15, 2015

(30) Foreign Application Priority Data
Jul. 7, 2014 (TW) 103212006

(51) Int. Cl. H05K 5/04; B21D 51/52

(52) U.S. Cl. CPC H05K 5/04; B21D 51/52

(57) ABSTRACT

This invention illustrates a compact casing structure, integrally made by press-fitting at least one metallic material and adapted to be connected with a preset electronic device. The casing structure has a base portion which has a first stress region and a plurality of second stress regions. The plurality of circle shape second stress regions are arranged in intervals within the first stress region. The larger stress first stress region combining with the lesser stress and toughness second stress region can improve the strength of whole casing structure relatively, and the thickness of the casing structure can be made lighter to thinner, same and the usage amount of the material required in the casing structure can be reduced, and the cost of the casing structure can be decreased.

### BACKGROUND OF THE INVENTION

1. Field of the Invention

The present disclosure relates to a compact casing structure, more particularly, to a casing structure which is made integrally by utilizing press-fitting method to have a first stress region and a plurality of second stress regions. The plurality of second stress regions are formed in circle shapes and arranged in intervals within the first stress region. The first stress region having higher stress can improve the strength of whole casing structure relatively, and the second stress regions have toughness and lower stress, so whole casing structure integrally made can have both of improved strength and toughness, and the thickness of the casing structure can be made lighter and thinner.

2. Description of the Related Art

With mature development of the electronic technology, current electronic devices are applied widely. In order to be carried with consumers conveniently, portable electronic devices such as laptop computers, tablet computers or intelligent portable communication devices are mainly advertised in light, thin, sturdy and durable. Therefore, a casing structure made of metal alloy, such as metal alloy of Al, Mg, Ti, and other metal, is researched and developed for the current electronic device. The main reason is that the casing structure made of metal alloy has characteristic of light weight, nice thermal conductivity, and anti-EMI, so the casing structure made of metal alloy is adopted by the electronic device manufacturer gradually.

However, for the casing structure made of metal alloy, for example, the casing structure made of Mg alloy is mainly manufactured by die casting. In the die casting process, an Mg alloy material is placed inside a mold for being pressed and cast, so that a casing structure can be formed by the Mg alloy material. However, the difficulty of using die casting method to form the casing structure having thinner thickness is higher relatively. The main factor is in that when the die casting thickness of the casing structure is thinner, the problem such as heat crack, oxidation, flow banding, insufficient strength (stress) or deformation, occurs easily on the casing structure and causes a low yield rate for the casing structure made of metal alloy. Moreover, metal casing structure is also formed by pressing in prior art. However, the difficulty of forming the casing structure having thinner thickness by pressing is also higher relatively. The main factor is that when a metal material is press-fitted by high pressure in a sealed mold, if the preset thickness of the metal material to be pressed is thinner, the pressure accepted by the surface of the metal material becomes larger, and the casing structure is easy to generate crack, even to break when the pressure exceeds the acceptable ductibility of the metal material, it causes the low yield rate for the casing structure made of metal alloy.

Therefore, if the yield rate of the manufacturing process of metal casing structure is desired to improve, the metal casing structure is hard to be further light and thin. On the contrary, if the metal casing structure is desired to be light and thin, the yield rate of the manufacturing process of the metal casing structure is hard to be improved, that is the problem of the current metal casing structure.

In order to solve above-mentioned problem in prior art, the inventor of the present disclosure has filed ROC patent issue no. M460497, titled “compact casing structure” already which utilizes a casing structure having a plurality of first stress regions and a plurality of second stress regions being elongated shapes and disposed in crisscross at a bottom portion thereof. The first stress regions having higher stress can improve the strength of whole casing structure relatively, and the second stress regions have toughness and lower stress, so whole casing structure integrally made can have both of improved strength and toughness, and the thickness of the casing structure can be made lighter and thinner, and the usage amount of the material required by the casing structure can be reduced. However, the first stress regions and the second stress regions are elongated shapes and disposed in crisscross, so it is easy to generate crack at the junction between the first stress region and the second stress region, and easy to cause the break of the casing structure.

### SUMMARY OF THE INVENTION

Main objective of the present disclosure is to provide a compact casing structure which is integrally made by press-fitting at least one metallic material and adapted to be connected with a preset electronic device. The casing structure has a base portion and a plurality of side walls at a peripheral of the base portion. The base portion and the plurality of side walls form an accommodating space correspondingly. The base portion has a first stress region and a plurality of second stress regions, and the plurality of second stress regions are circle shapes and arranged in intervals in the first stress region. A stress of the first stress region is higher than stress of the second stress region. Therefore, the strength of whole casing structure can be improved by the first stress region having higher stress. Because of the second stress region having toughness and the smaller stress, whole casing structure integrally made can have both of improved strength and toughness, and the thickness of the casing structure (thickness of base portion of the casing structure) can be made lighter and thinner, and the usage amount of the material required in the casing structure can be reduced, and the cost of the casing structure can be decreased.

By the second stress regions being circle shapes and arranged in intervals within the first stress region, it is not easy to generate crack at the junction between the first stress region and the second stress region, so that the strength of whole casing structure can be further improved.

### BRIEF DESCRIPTION OF THE DRAWINGS

The detailed structure, operating principle and effects of the present disclosure will now be described in more details hereinafter with reference to the accompanying drawings that show various embodiments of the present disclosure as follows.

FIG. 1 is a local section view of an exterior appearance of a casing structure of the present disclosure.

FIG. 2 is a schematic view of a first manufacturing process of the casing structure of the present disclosure.

FIG. 3 is a schematic view of a second manufacturing process of the casing structure of the present disclosure.

FIG. 4 is a schematic view of a third manufacturing process of the casing structure of the present disclosure.

FIG. 5 is a schematic view of a fourthly manufacturing process of the casing structure of the present disclosure.

FIG. 6 is an enlarged local view of a region marked by “A” in the FIG. 5 of the present disclosure.

### DETAILED DESCRIPTION OF THE PREFERRED EMBODIMENTS

Reference will now be made in detail to the exemplary embodiments of the present disclosure, examples of which are illustrated in the accompanying drawings. Therefore, it is to be understood that the foregoing is illustrative of exemplary embodiments and is not to be construed as limited to the specific embodiments disclosed, and that modifications to the disclosed exemplary embodiments, as well as other exemplary embodiments, are intended to be included within the scope of the appended claims. These embodiments are provided so that this disclosure will be thorough and complete, and will fully convey the inventive concept to those skilled in the art. The relative proportions and ratios of elements in the drawings may be exaggerated or diminished in size for the sake of clarity and convenience in the drawings, and such arbitrary proportions are only illustrative and not limiting in any way. The same reference numbers are used in the drawings and the description to refer to the same or like parts.

It will be understood that, although the terms ‘first’, ‘second’, ‘third’, etc., may be used herein to describe various elements, these elements should not be limited by these terms. The terms are used only for the purpose of distinguishing one component from another component. Thus, a first element discussed below could be termed a second element without departing from the teachings of embodiments. As used herein, the term “or” includes any and all combinations of one or more of the associated listed items.

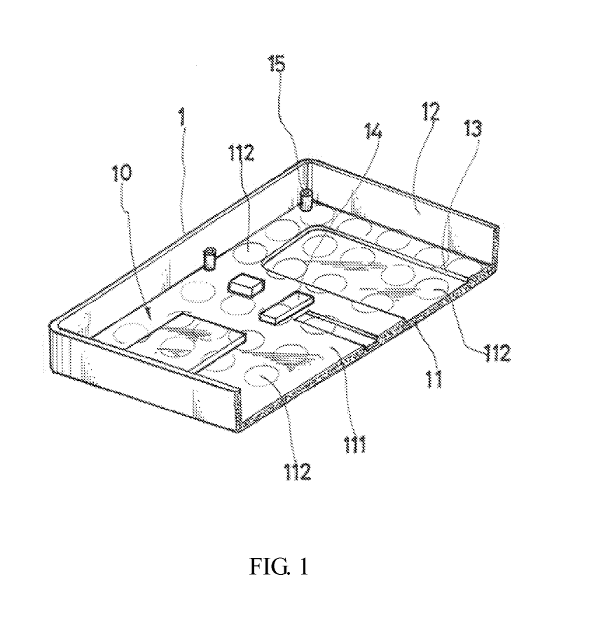

Please refer to FIG. 1, the present disclosure illustrates a compact casing structure which is integrally made by press-fitting at least one metallic material and adapted to be connected with a preset electronic device. The casing structure 1 has a base portion 11 and a plurality of side walls 12 at a peripheral of the base portion 11. The base portion 11 and the plurality of side walls 12 form an accommodating space correspondingly. In the casing structure 1, the base portion 11 is made integrally and has a first stress region 111 and a plurality of second stress regions 112. The plurality of second stress regions 112 are circle shapes and arranged in intervals within the first stress region 111. The density of the first stress region 111 is lower than density of the second stress regions 112, so that a stress (strength) of the first stress region 111 is higher than a stress (strength) of the second stress region 112. In addition, the base portion 11 of the casing structure 1 is provided with at least one concave portion 13, at least one convex portion 14 and at least one connection portion 15 corresponding to the accommodating space 10.

The first stress region 111 formed in the base portion 11 has lower density and higher stress, so the strength of whole casing structure 1 of the present disclosure can be improved. In addition, the second stress regions 112 formed in the base portion 11 have higher density and lower stress, so the second stress regions 112 have extension toughness. Therefore, the casing structure 1 made integrally can have both of improved strength and toughness, the thickness of the casing structure 1 (thickness of base portion 11 of the casing structure 1) can be made lighter and thinner correspondingly, and the usage amount of the material required in the casing structure 1 can be reduced, and the cost of the casing structure 1 can be decreased.

In addition, because of the second stress regions being circle shapes and arranged in intervals within the first stress region 112, it is not easy to generate crack at a junction between the first stress region 111 and the second stress region 112, so that the strength of whole casing structure 1 can be further improved.

Preferably, the metallic material includes Al, Mg, Ti or other metal alloy. The second stress regions 112 in circle shapes can be arranged with intervals in an array within the first stress region 111; alternatively, the second stress regions 112 in circle shapes can be formed with intervals in other arrangement within the first stress region 111.

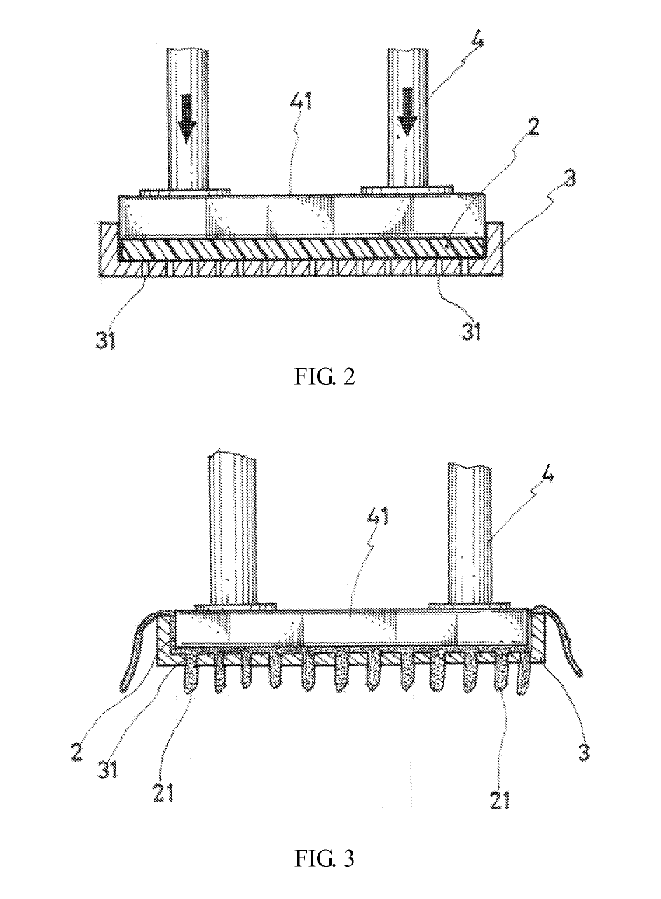

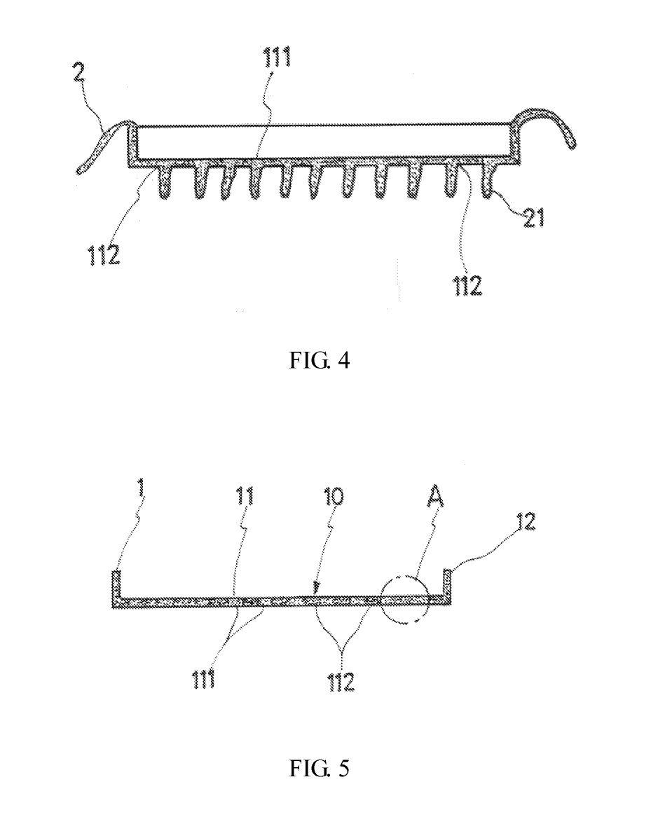

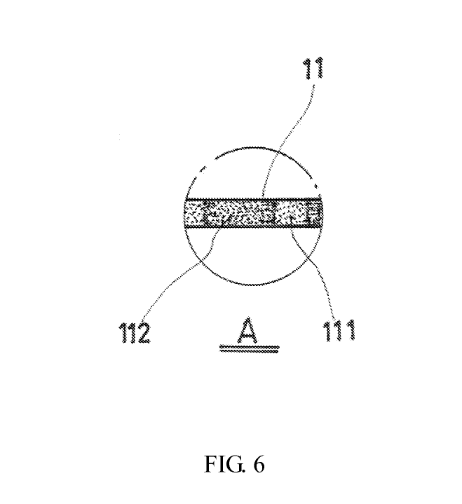

Please refer to FIG. 2 through FIG. 6. The present disclosure illustrates an implement method as an example. In order to manufacture the casing structure 1 made integrally illustrated in the present disclosure, a raw case blank 2 of metallic material is disposed in a mold 3 which has a plurality of discharge gates 31 being circle shapes at bottom portion thereof, and the raw case blank 2 is press-fitted by using the high pressure press-fitting method, it means that a press-fitting part 41 of a high pressure press-fitting device 4 applies a preset pressure to the raw case blank 2 inside the mold 3, so the raw case blank 2 can form a raw case blank flow material 21 by the remaining material flowing from the circular discharge gate 31 while the raw case blank 2 is compressed by the preset pressure, whereby the areas of the raw case blank 2 corresponding to positions of the circular discharge gates 31 are not press-fitted completely and a second stress regions 112 having circle shapes and high density are formed correspondingly. Next, the flow material cannot outflow via the area of the raw case blank 2 not corresponding to the positions of the circular discharge gates 31 to form the raw case blank flow material 21, so the area of the raw case blank 2 not corresponding to the positions of the circular discharge gates 31 is press-fitted completely to form the first stress region 111 having low density. Next, after the raw case blank flow material 21 and other remaining material of the raw case blank 2 are milled, the casing structure 1 is formed.

Therefore, the base portion 11 of the casing structure 1 made integrally has a first stress region 111 with lower density, and a plurality of second stress regions 112 with higher density. The strength of whole casing structure 1 can be improved by the first stress region 111 formed in the base portion 11 and having lower density and higher stress. In addition, the second stress regions 112 formed in the base portion 11 have smaller stress and the higher density, so the second stress regions 112 have extension toughness, whereby the casing structure 1 can have both improved strength and toughness, and the thickness of the casing structure 1 (thickness of base portion 11 of the casing structure 1) can made by press-fitting to be lighter and thinner, so that the usage amount of the material required in the casing structure 1 can be reduced, and the cost of the casing structure 1 can be decreased.

An outer surface of the base portion 11 of the casing structure 1 is provided with knurling, or the outer surface of the base portion 11 of the casing structure 1 can be spray-coated with color or image.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A compact casing structure, integrally made by press-fitting at least one metallic material, the casing structure including a base portion which has a first stress region and a plurality of second stress regions, the plurality of second stress regions formed in circle shapes and arranged in intervals within the first stress region, wherein the density of the first stress region is lower than density of the second stress regions, so that a stress of the first stress region is higher than stresses of the second stress regions.

2. The compact casing structure according to claim 1, wherein the casing structure has a plurality of side walls at a peripheral of the base portion, and the base portion and the plurality of side walls form an accommodating space correspondingly.

3. The compact casing structure as defined in claim 2, wherein the base portion of the casing structure is provided with at least one concave portion corresponding to the accommodating space.

4. The compact casing structure as defined in claim 2, wherein the base portion of the casing structure is provided with at least one convex portion corresponding to the accommodating space.

5. The compact casing structure as defined in claim 2, wherein the base portion of the casing structure is provided with at least one connection portion corresponding to the accommodating space.

6. The compact casing structure according to claim 1, wherein an outer surface of the base portion of the casing structure is provided with knurling.

7. The compact casing structure according to claim 1, wherein an outer surface of the base portion of the casing structure is spray-coated with color or image.
